(19) United States
(12) Patent Application Publication
(10) Pub. No.: US 2005/0173784 A1
(43) Pub. Date: Aug. 11, 2005

(54) Stacked semiconductor device having mask mounted in between stacked dies

(75) Inventors: Jin-Chung Bai, Taipei County (TW); Kuang-Pao Cheng, Hsinchu City (TW); Chi-Pang Huang, Taoyuan County (TW)

Correspondence Address: BACON & THOMAS, PLLC, 625 SLATERS LANE, FOURTH FLOOR, ALEXANDRIA, VA, 22314, US

(73) Assignee: Stack Devices Corp., Miaoli County (TW)

(21) Appl. No.: 10/806,167

(22) Filed: Mar. 23, 2004

(30) Foreign Application Priority Data
Feb. 10, 2004 (TW) 93103111

(51) Int. Cl. H01L 29/18

(52) U.S. Cl. 257/678

(57) ABSTRACT

A stacked semiconductor device has a substrate having a conductor pattern thereon and the conductor pattern has a plurality of pads. A first die is mounted on the substrate and is electrically connected to the pads of the conductor pattern by gold wires. A first insulating layer is mounted on the substrate to cover the first die and the gold wires. A mask, which has a top and an annular sidewall, is mounted on the substrate to cover the first insulating layer and the first die. A second die is mounted on the top of the mask and is electrically connected to the pads of the connector pattern by gold wires. A second insulating layer is mounted on the substrate to cover the second die and the gold wires.

### BACKGROUND OF THE INVENTION

1. Field of the Invention

The present invention relates generally to a semiconductor device, and more particularly to a stacked semiconductor device, which has a mask mounted in between the stacked dies.

2. Description of the Related Art

Semiconductor devices are applied to computer devices, industry equipment, automobiles and military equipment. Recently, the semiconductor devices are applied to communication devices.

In communication device, the Radio Frequency Integral Circuit (R.F. IC) is the most important part of the semiconductor device. The R.F. IC is the device emitting and receiving the radio frequency signals. Such semiconductor device is provided with a metal mask shielding the R.F. IC. The metal shield is to shelter the R.F. IC to prevent the radio frequency signals generated from the R.F. IC interfering with the work of other devices.

In a stacked semiconductor device, the R.F. IC is stacked with other dies and the metal mask shields all of the stacked dies. Such semiconductor device makes a critical interference of the dies in the metal mask by the R.F. IC. And further more, the metal shield has a greater size.

### SUMMARY OF THE INVENTION

The primary objective of the present invention is to provide a stacked semiconductor device, which a mask with smaller size is mounted.

The secondary objective of the present invention is to provide a stacked semiconductor device, which the dies stacked in a stable condition.

The third objective of the present invention is to provide a stacked semiconductor device, which makes a greater die can be stacked on a smaller die.

According to the objectives of the present invention, a stacked semiconductor device comprises a substrate having a conductor pattern thereon and the conductor pattern has a plurality of pads. A first die is mounted on the substrate and is electrically connected to the pads of the conductor pattern. A first insulating layer is mounted on the substrate to cover at least a portion of the first die. A mask, which has a top and an annular sidewall, is mounted on the substrate to cover the first insulating layer and the first die, and a second die is mounted on the top of the mask and is electrically connected to the pads of the connector pattern.

### BRIEF DESCRIPTION OF THE DRAWINGS

FIG. 1 is a top view of a first preferred embodiment of the present invention;

FIG. 2 is a sectional view along the 2-2 line of FIG. 1, and

FIG. 3 is a sectional view of a second preferred embodiment of the present invention.

### DETAILED DESCRIPTION OF THE INVENTION

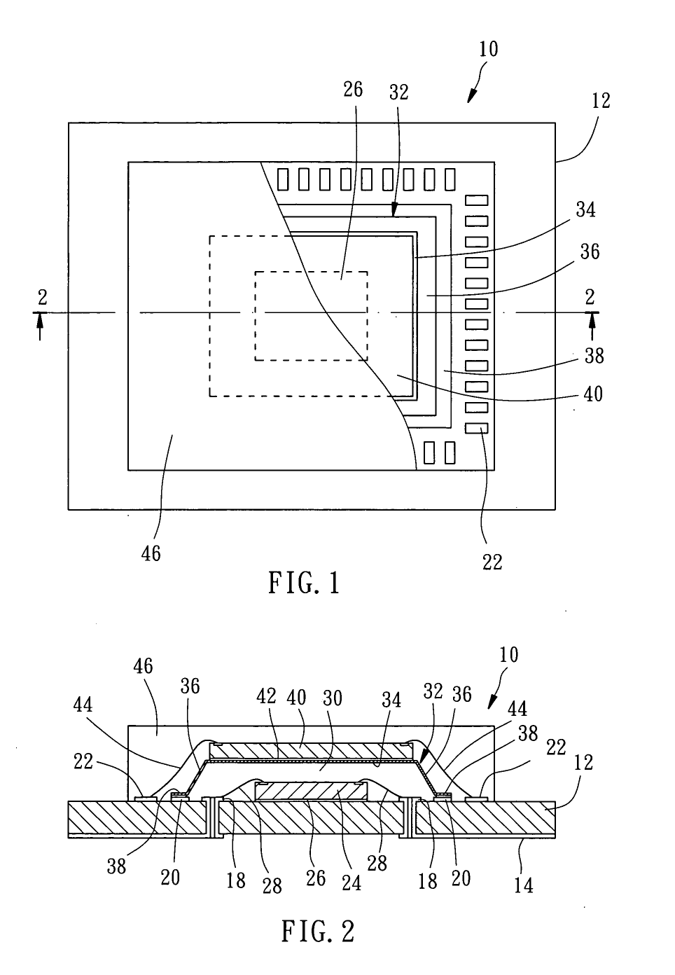

As shown in FIG. 1 and FIG. 2, a stacked semiconductor device 10 of the first preferred embodiment of the present invention comprises:

A substrate 12 has a conductor pattern 14 thereon. The conductor pattern 14 ha a plurality of pads 18, 20, 22.

A first die 24, which has a radio frequency integral circuit, is bonded on the substrate 12 by an adhesive layer 26 and is electrically connected to the predetermined pads 18 of the conductor pattern 12 by gold wires 28. In other words, the first die 24 is electrically connected to the conductor pattern 14 by wire bonding.

A first insulating layer 30, which is made of epoxy resin, glue or other insulating materials, is provided on the substrate 12 covering the first die 24 and the gold wires 28.

A mask 32 is a cup-like element having a top 34 and an annular sidewall 36. On an edge of the sidewall 36 is a connector portion 38. The mask is mounted on the first insulating layer 30 with the connector portion 38 thereof electrically connected to the pads 20 of the connector pattern 14 to cover the first die 24 therein. The mask 32 is made of iron, aluminum, copper or other metal to shelter the radio frequency generated from the first die emitting out.

The mask 32 is preferred filled with first insulating layer 30 therein to makes no air in the mask 32, such that the stacked structure is stronger. The connector portion 38 of the mask 32 is electrically connected to the pads 20 of the connector pattern 14 via wire bonding or via conductive paste.

A second die 40 is bonded on the top 34 of the mask 32 by an adhesive layer 42 and is electrically connected to the pads 22 of the conductor pattern 14 via gold wires 44.

A second insulating layer 46 is mounted on the substrate 12 covering the second die 42 and the gold wires 44.

It has to be mentioned that there could be another die(s) stacked on the second insulating layer 40 (not shown in FIGS.).

The mask is mounted in between the stacked dies, so that the mask has a smaller size than the conventional mask has. The mask further covers the first die, while it is a R.F. IC die, only that prevents the first die interfering with other dies.

The mask forms a rigid base in the stacked dies, which enhances the strength of the stacked dies. In other words, the stacked dies are divided into two stacks, the dies under the mask are stacked on the substrate and the rest dies are stacked on the mask. As a result, there could be more dies stacked without having to worry about the strength of the stack. The mask of the present invention achieves the function of enhancement of the strength of the stacked dies, whether the first die is a R.F. IC die or not.

The size of the top of the mask is greater than the first die so that the second die might have a size greater that the first die and the second die is still stacked in a stable condition. In other words, the conventional stacked dies have the smaller die stacked on the greater die, but the present invention allows the greater die stacked on the smaller die.

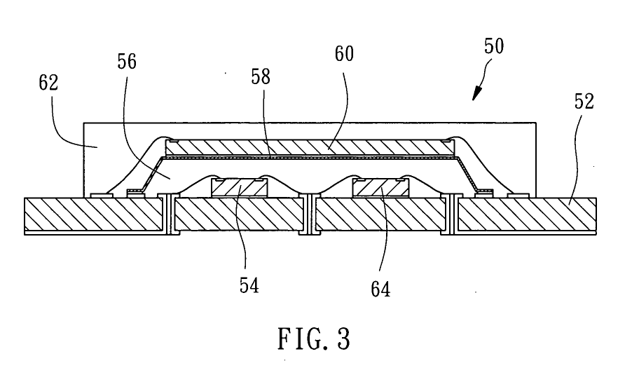

FIG. 3 shows a stacked semiconductor device 50 of the second preferred embodiment of the present invention, which is similar to the stacked semiconductor device 10 of the first preferred embodiment, having a substrate 52 on which a first die 54, a first insulating layer 56, a mask 58, second die 60 and a second insulating layer 62 are stacked. The stacked semiconductor device 50 of the second preferred embodiment further has a third die 64 is bonded on the substrate 52 beside the first die 52. The mask 58 covers both of the first die 54 and third die 62.

The third die also can be stacked on the first die (not shown in FIGS.) and there might be three or more dies arranged under the mask. The first die and the second die can be electrically connected to the pads of the conductor pattern by wire bonding as described above or by flip chip.

1. A stacked semiconductor device, comprising:
a substrate having a conductor pattern thereon and the conductor pattern having a plurality of pads;
a first die mounted on the substrate and electrically connected to the pads of the conductor pattern;
a first insulating layer mounted on the substrate to cover at least a portion of the first die;
a mask, which has a top and an annular sidewall, mounted on the substrate to cover the first insulating layer and the first die, and
a second die mounted on the top of the mask and electrically connected to the pads of the connector pattern.

2. The stacked semiconductor device as defined in claim 1, further comprising a second insulating layer mounted on the substrate to cover the second die.

3. The stacked semiconductor device as defined in claim 1, wherein the first die has a radio frequency integral circuit.

4. The stacked semiconductor device as defined in claim 1, wherein in the mask is filled with the first insulating layer.

5. The stacked semiconductor device as defined in claim 1, further comprising an adhesive layer in between the second die and the top of the mask.

6. The stacked semiconductor device as defined in claim 1, further comprising a third die covered by the mask.

7. The stacked semiconductor device as defined in claim 6, wherein the third die is mounted on the substrate beside the first die.

8. The stacked semiconductor device as defined in claim 6, wherein the third die is stacked on the first die.

9. The stacked semiconductor device as defined in claim 1, wherein the mask further has a connector portion on the sidewall to be electrically connected to the pads of the conductor pattern.

10. The stacked semiconductor device as defined in claim 1, wherein a size of the second die is greater than a size of the first die.

11. The stacked semiconductor device as defined in claim 1, further comprising wires electrically connecting the first die to the pads of the conductor pattern and the first insulating layer covers both of the first die and the wires.

12. The stacked semiconductor device as defined in claim 1, further comprising wires electrically connecting the second die to the pads of the conductor pattern and the second insulating layer covers both of the first die and the wires.
